(19) United States
(12) Patent Application Publication
(10) Pub. No.: US 2008/0257263 A1
(43) Pub. Date: Oct. 23, 2008

(54) COOLING SHIELD FOR SUBSTRATE PROCESSING CHAMBER

(75) Inventors: Cristopher Mark Pavloff, San Francisco, CA (US); Kathleen Scheible, San Francisco, CA (US)

Correspondence Address: JANAH & ASSOCIATES, P.C., 650 DELANCEY STREET, SUITE 106, SAN FRANCISCO, CA, 94107, US

(73) Assignee: Applied Materials, Inc.

(21) Appl. No.: 11/738,788

(22) Filed: Apr. 23, 2007

(51) Int. Cl. C23C 14/00

(52) U.S. Cl. 118/723 R

(57) ABSTRACT

A process kit comprises an upper shield to encircle a sputtering target in a substrate processing chamber, to reduce deposition of process deposits on the chamber components and the overhanging edge of the substrate. The shield described is of unitary construction with a top ring, support ledge and cylindrical band having a plurality of steps.

### CROSS-REFERENCE

This application is related to co-pending Non-Provisional application Ser. No. 11/668,461, filed on Jan. 29, 2007, entitled “PROCESS KIT FOR SUBSTRATE PROCESSING CHAMBER” by Pavloff et al, which is incorporated herein by reference in it's entirety.

### BACKGROUND

Embodiments of the present invention relate to a shield for a substrate processing chamber.

In the manufacture of integrated circuits and displays, a substrate such as a semiconductor wafer or display panel is placed in a process chamber and processing conditions are set in the chamber to deposit or etch material on the substrate. A typical process chamber comprises chamber components that include an enclosure wall that encloses a process zone, a gas supply to provide a process gas in the chamber, a gas energizer to energize the process gas to process the substrate, a gas exhaust to exhaust and remove spent gas and maintain a gas pressure in the chamber, and a substrate support to hold the substrate. Such chambers can include, for example, sputtering or physical vapor deposition (PVD), chemical vapor deposition (CVD), and etching chambers.

In a PVD chamber, a target is sputtered to cause sputtered target material to deposit on a substrate facing the target. In the sputtering process, a process gas comprising an inert and reactive gas is supplied into the chamber. The process gas is energized to form energetic ions which bombard the target causing sputtering material to be knocked off the target and deposited as a film on the substrate. In these sputtering processes, the material sputtered from the target can redeposit along shields or liners used to receive the sputtered material to protect and prevent deposition on the chamber walls and other chamber component surfaces. However, accumulation and build-up of the sputtered and redeposited material on the shields or liners is undesirable because such accumulated deposits can debond and flake off, falling inside and contaminating the chamber and its components. To avoid such an outcome, the shields and liners require disassembly and cleaning after only a few process cycles, which is highly inefficient and costly due to the requisite labor involved.

Particle shedding and flaking of accumulated deposits may result from poor thermal conductivity of the shields, due in part to the high thermal resistance at the interface between components of the shields as well as the interface between the shield and adapter. There is thus little temperature control of existing shields and liners and the shedding and flaking of particles from the shields and liners is due to the shields experiencing large temperature swings with the cyclic thermal loading of the shields from exposure to plasma. The large temperature swings result in the expansion and contraction of the shields, which in turn generates thermal stresses in the structure of the shields. Due to the difference in coefficients of thermal expansion between shields or liners and the material deposited thereupon, such as high stress films, there can be peeling or spalling of the sputtered material formed on the shields and liners after a process cycle is completed.

Therefore, it is desirable to have shields that reduce flaking of accumulated deposits from their surfaces. It is further desirable to increase the thermal conductivity of the shields and liners to control the temperature of the shields and liners during processing of the substrate, to reduce the flaking of particles from the shield and liner surfaces. It is also desirable to have shields and liners which are designed to receive and tolerate ever larger amounts of accumulated deposits and increase adhesion of those deposits to the shields and liners. It is further desirable to have a shield or liner with fewer parts or components, as well as having components that are shaped and arranged in relationship to one another to reduce the amounts of sputtered deposits formed on the internal surfaces of the process chamber.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1A is a schematic sectional side view of a substrate processing chamber showing process kit components and a target;

FIG. 1B is a sectional side view of an embodiment of the upper shield;

FIG. 2A is a simplified top view of the upper shield;

FIG. 2B is an isometric view of an embodiment of the upper shield; and

FIG. 3 is a cross-sectional view of the upper portion of the upper shield connected to an adapter.

### DESCRIPTION

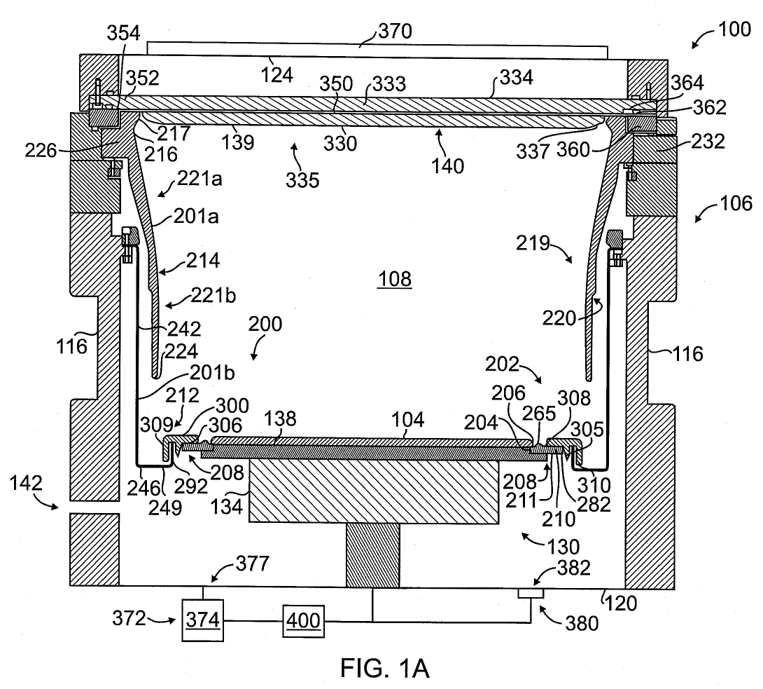

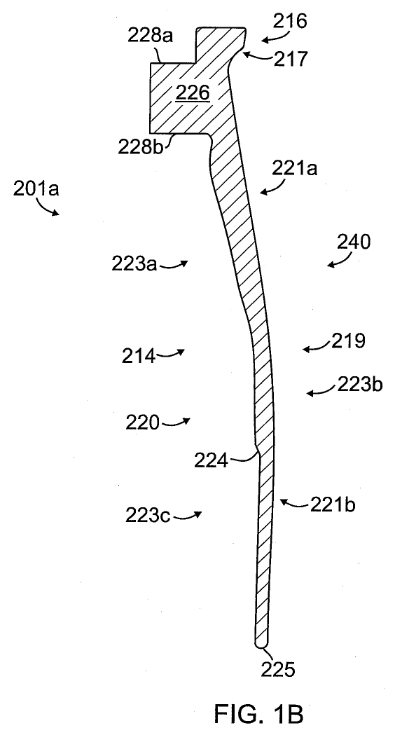

An example of a suitable process chamber 100 capable of processing a substrate 104 is shown in FIG. 1A. The chamber 100 comprises enclosure walls 106 that enclose a process zone 108. The walls 106 include sidewalls 116, a bottom wall 120 and a ceiling 124. The chamber 100 can be a part of a multi-chamber platform having a cluster of interconnected chambers connected by a substrate transfer mechanism, such as a robot arm, that transfers substrates 104 between the chambers 100. In the version shown, the process chamber 100 comprises a sputter deposition chamber, also known as a physical vapor deposition or PVD chamber, which is capable of sputter depositing material such as, for example, one or more of aluminum, copper, tantalum, titanium and tungsten, on a substrate 104.

The chamber 100 comprises a substrate support 130, which comprises a pedestal 134 to support the substrate 104. The pedestal 134 has a substrate receiving surface 138 having a horizontal plane substantially parallel to a sputtering surface 139 of an overhead sputtering target 140. The substrate receiving surface 138 of the pedestal 134 receives and supports the substrate 104 during processing. The pedestal 134 may include an electrostatic chuck or a heater, such as an electrical resistance heater or heat exchanger. In operation, a substrate 104 is introduced into the chamber 100 through a substrate loading inlet 142 in the sidewall 116 of the chamber 100 and is placed on the receiving surface 138 of the substrate support 130. The support 130 can be lifted or lowered by support lift bellows and a lift finger assembly can be used to lift and lower the substrate 104 onto the support 130 during placement of a substrate 104 on the substrate support 130. The pedestal 134 can be maintained at an electrically floating potential or grounded during plasma operation.

The chamber 100 comprises a process kit 200 for placement about the sputtering target 140 and the substrate support 130. The process kit 200 comprises various components that can be easily removed from the chamber 100, for example, to clean sputtering deposits off the component surfaces, replace or repair eroded components, and to adapt the chamber 100 for other processes. In one version, the process kit 200 comprises an upper shield 201a, a lower shield 201b and a ring assembly 202 for placement about a peripheral wall 204 of the substrate support 130 that terminates before an overhanging edge 206 of the substrate 104 placed on the receiving surface 138 of the substrate support 130. The ring assembly 202 comprises a deposition ring 208 and a cover ring 212. The deposition ring 208 and cover ring 212 cooperate with one another to reduce formation of sputter deposits on the peripheral walls 204 of the support 130 and the overhanging edge 206 of the substrate 104.

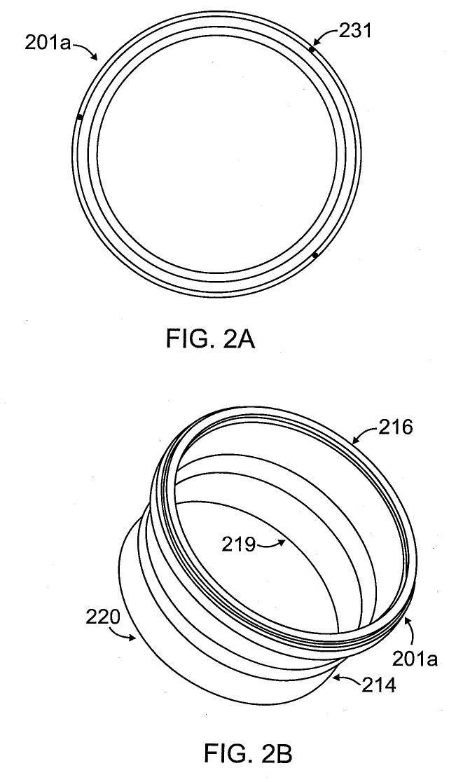

Referring to FIGS. 1A, 1B, 2A and 2B, the upper shield 201a has a diameter sized to encircle the sputtering surface 139 of a sputtering target 140 that faces the substrate support 130, the outer periphery of the substrate support 130, and shadows the sidewalls 116 of the chamber 100. The upper shield 201a serves to reduce deposition of sputtering deposits originating from the sputtering surface 139 of the sputtering target 140 onto the surfaces of the support 130, overhanging edge 206 of the substrate 104, sidewalls 116 and bottom wall 120 of the chamber 100.

The upper shield 201a comprises a top ring 216 having a radially inward bulge 217. The bulge 217 has an arcuate surface that is shaped to surround an inclined perimeter edge of the sputtering target 140. The bulge 217 of the top ring 216 serves to decrease or minimize the amount of space between the top ring 216 and the sputtering target 140 by creating a smaller region for unwanted sputtered deposits. In addition, the arcuate surface of the inward bulge 217 of the top ring 216 makes it difficult for sputtered deposits to adhere thereto.

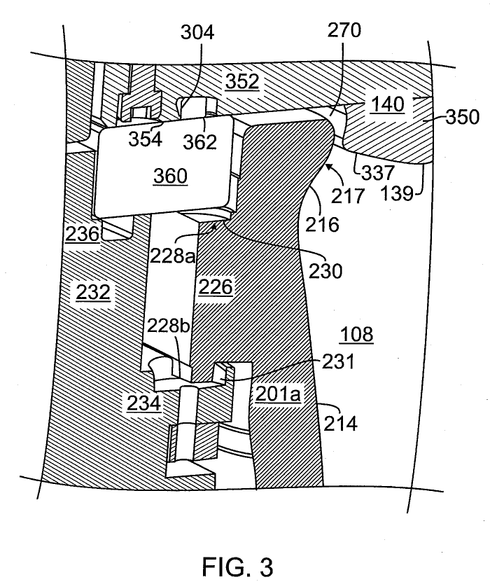

Referring to FIGS. 1B and 3, there is a support ledge 226 immediately below the top ring 216. The support ledge 226 extends radially outward towards the sidewalls 116 of the chamber 100. The support ledge 226 comprises a top and bottom surface 228a,b. The top surface 228a has a plurality of cutouts 230, with each cutout 230 comprising a semicircular shape. In one version, the support ledge 226 has three cutouts 230. The bottom surface 228b of the support ledge 226 comprises a plurality of protrusions 231 to align the upper shield 201a with an annular adapter 232 supporting the upper shield 201a. Each protrusion 231 comprises a semicircular shape, and in one version, the support ledge 226 has three protrusions 231. The cutouts 230 on the top surface 228a of the support ledge 226 are above and in direct vertical alignment with the protrusions 231 on the bottom surface 228b of the support ledge 226, and used to align the protrusions 231 with the similarly shaped cutouts on the adapter 232. The plurality of protrusions 231 on the bottom surface 228b of the support ledge 226 serve to precisely align the upper shield 201a to the adapter 232. This alignment helps to tightly control the spacing between the target 140 and the upper shield 201a to minimize arcing and secondary plasma occurrences, as well as maintain a constant voltage between process kit 200 changes and chamber matching. The support ledge 226 of the upper shield 201a is secured to the adapter 232 by a plurality of screws. In one version, the plurality of screws is 12 screws. Securing the upper shield 201a to the annular adapter 232 provides temperature control of the upper shield 201a.

Extending downward from the top ring 216 of the upper shield 201a is a cylindrical band 214 having a radially inward 219 and outward surface 220. The radially inward surface 219 of the band 214 has both a sloped plane 221a and a substantially vertical plane 221b. In one version, the sloped plane 221a has an angle of from about 7 to about 14 degrees relative to the substantially vertical plane 221b of the cylindrical band 214. The radially inward surface 219 of the band 214 has an inward sloping plane 221a above the substantially vertical plane 221b to, for example, provide a surface for sputtered deposits that have flaked off from the top ring 216 and for sputtered deposits from the periphery of the target 140, to attach thereto. This effectively minimizes the contamination of substrate 104, especially around the edge.

The radially outward surface 220 of the cylindrical band 214 comprises a plurality of steps 223. The steps 223 are joined to each other by inclined planes 224. The lowest step 223 on the cylindrical band 214 extends downwardly from the inclined plane 224 and terminates in a rounded edge 225. In one version, the cylindrical band 214 has three steps 223a,b,c. In one version, the third step 223c of the band 214 has a thickness that is less than the first and second steps 223a,b. In one version, the thickness of the third step 223c is from about 0.05 to about 0.3 inches.

The top ring 216, support ledge 226 and cylindrical band 214 form a unitary monolith structure. For example, the entire upper shield 201a can be made from conducting materials such as 300 series stainless steel, or as in one version, aluminum. A unitary upper shield 201a is advantageous over prior upper shields which have included multiple components, often two separate pieces to make up the upper shield, because a unitary upper shield 201a is less difficult and laborious to remove for cleaning than a multiple component shield. Further, the single piece upper shield 201a has a continuous surface that is exposed to the sputtering deposits without corners or interfaces that are more difficult to clean out; undesirably, interfaces may be a particle generation source. Having a single piece upper shield 201a is also more thermally uniform than multiple component shields, both for heating during the periodic maintenance as well as cooling during processes when the plasma is heating the upper shield 201a. The single piece upper shield 201a also shields the chamber walls 106 from sputter deposition during process cycles.

In one version, the surface of the upper shield 201a is treated with a twin-wire aluminum arc-spray coating, such as, for example, CleanCoat™, available from Applied Materials, Santa Clara, Calif. CleanCoat™ is applied to substrate processing chamber components, such as the upper shield 201a, to reduce particle shedding of deposits on the upper shield 201a, and thus prevent contamination in the chamber 100. In one version, the twin-wire aluminum arc-spray coating on the upper shield 201a has an average surface roughness of from about 600 to about 2600 microinches.

The upper shield 201a has exposed surfaces 240 facing the center of the plasma zone 108 in the chamber 100. Optionally, the exposed surfaces may be bead blasted to have a surface roughness of about 200 to about 300 microinches. The bead blasted surfaces help the twin-wire aluminum arc-spray coating adhere to the surfaces of the upper shield 201a and may also serve to reduce particle shedding and prevent contamination within the chamber 100.

The lower shield 201b is placed about the outer surface 220 of the cylindrical band 214 of the upper shield 201a and shadows the sidewalls 116 of the chamber 100. In one version, the lower shield 201b encircles at least part of the outer surface 220 of the cylindrical band of the upper shield 201a. The lower shield 201b serves to reduce deposition of sputtering deposits originating from the sputtering surface 139 of the sputtering target 140 and the surfaces of the upper shield 201a, onto the surfaces of the support 130, overhanging edge 206 of the substrate 104, sidewalls 116 and bottom wall 120 of the chamber 100. The lower shield 201b comprises an annular band 242 which extends downward into a curved joint 246. The curved joint 246 extends horizontally into an inwardly projecting lip 249. The inwardly projecting lip 249 comprises a radially inward edge 252 which at least partially surrounds the peripheral edge 204 of the substrate support 130. In one version, the inwardly projecting lip 249 is sloped downwards. The downward slope of the inwardly projecting lip 249 makes it such that sputtered deposits that may flake off this surface may then collect in the rounded corner where the lip 249 meets the radially inward edge 252. Such an area is desirable as it is difficult for the plasma to pick up deposits from this area and redeposit them on the substrate 104.

The deposition ring 208 comprises an annular band 210 that extends about and surrounds the peripheral wall 204 of the support 130 as shown in FIG. 1A. The annular band 210 comprises an inner lip 211 which extends transversely from the band 210 and is substantially parallel to the peripheral wall 204 of the support 130. The inner lip 211 terminates immediately below the overhanging edge 206 of the substrate 104. The inner lip 211 defines an inner perimeter of the deposition ring 208 which surrounds the periphery of the substrate 104 and substrate support 130 to protect regions of the support 130 that are not covered by the substrate 104 during processing. For example, the inner lip 211 surrounds and at least partially covers the peripheral wall 204 of the support 130 that would otherwise be exposed to the processing environment, to reduce or even entirely preclude deposition of sputtering deposits on the peripheral wall 204.

The annular band 210 of the deposition ring 208 has an arcuate protuberance 265 that extends along the central portion of the band 210, with radially inward dips on either side of the arcuate protuberance 265. An open inner channel lies between the inner lip 211 and the arcuate protuberance 265. The open inner channel extends radially inward to terminate at least partially below the overhanging edge 206 of the substrate 104. The open inner channel facilitates the removal of sputtering deposits from these portions during cleaning of the deposition ring 208. The deposition ring 208 also has a ledge 282 which extends outward and is located radially outward of the arcuate protuberance 265. The ledge 282 serves to support the cover ring 212.

The deposition ring 208 can be made by shaping and machining a ceramic material, such as aluminum oxide. The ceramic material is molded and sintered using conventional techniques such as isostatic pressing, followed by machining of the molded sintered preformed using suitable machining methods to achieve the shape and dimensions required. The annular band 210 of the deposition ring 208 may comprise an exposed surface that is grit blasted with a grit size suitable to achieve a predefined surface roughness. Optionally, the surface of the deposition ring 208 may be treated with a twin-wire arc-sprayed aluminum coating, such as CleanCoat™, to reduce particle shedding and contamination within the chamber 100.

The cover ring 212 of the ring assembly 202 is for placement about the substrate support and encircles and at least partially covers the deposition ring 208 to receive, and thus, shadow the deposition ring 208 from the bulk of the sputtering deposits. The cover ring 212 is fabricated from a material that can resist erosion by the sputtering plasma, for example, a metallic material such as stainless steel, titanium or aluminum, or a ceramic material, such as aluminum oxide. Optionally, the surface of the cover ring 212 may also be treated with a twin-wire arc-sprayed aluminum coating, such as CleanCoat™.

The cover ring 212 comprises an undersurface that is spaced apart from, overlies, and at least partially covers the ledge 282 of the deposition ring 208 to define a narrow gap which impedes travel of plasma species through the gap. The constricted flow path of the narrow gap restricts the build-up of low-energy sputter deposits on the mating surfaces of the deposition ring 208 and cover ring 212, which would otherwise cause them to stick to one another or to the peripheral overhang edge 206 of the substrate 104.

As shown in FIG. 1A, the cover ring 212 comprises a wedge 300 comprising a top surface 302 about the substrate support 130 and a footing 306 which rests on the ledge 282 of the deposition ring 208 to support the cover ring 212. The footing 306 extends downwardly from the wedge 300 to press against the deposition ring 208 substantially without cracking or fracturing the ring 208. The top surface of the cover ring 212 serves as a boundary to contain the sputtering plasma within the process zone 108 between the target 140 and the support 130, receives the bulk of the sputtering deposits, and shadows the deposition ring 208.

The wedge 300 extends inward into a projecting brim 308, which overlies the narrow gap between the cover ring 212 and the deposition ring 208. The projecting brim 308 extends outward and then downward into an outer leg 309 terminating in a rounded bottom 310. The cover ring 212 also has an inner leg 305 that extends downwardly from the annular wedge 300. The inner leg 305 is located radially outward of the footing 306 of the wedge 300. The inner leg 305 has a smaller height than the outer leg 309. The inner leg 305 has a sloped inner surface that meets the side of the deposition ring 208 to form yet another convoluted pathway which impedes travel of plasma species and glow discharges to the surrounding area.

The sputtering target 140 is positioned facing a substrate 104 during processing of the substrate 104 in the chamber 100. The sputtering target 140 comprises a sputtering plate 330 mounted to a backing plate 333. The sputtering plate 330 comprises a metal material comprising, for example, one or more of aluminum, copper, tungsten, titanium, cobalt, nickel and tantalum, to be sputtered onto the substrate 104. The sputtering plate 330 comprises a central cylindrical mesa 335 having the sputtering surface 139 that forms a plane that is parallel to the plane of the substrate 104. An annular inclined rim 337 surrounds the cylindrical mesa 335. The annular inclined rim 337 is adjacent to the top ring 216 of the cylindrical band 214 of the upper shield 201 in the chamber 100, and the area therebetween forms a convoluted gap 270 comprising a dark space region. This profile serves as a labyrinth that impedes the passage of sputtered plasma species through the gap 270, and thus, reduces the accumulation of sputtered deposits on the surfaces of the peripheral target region.

The backing plate 333 is made from a metal such as, for example, stainless steel, aluminum, and copper alloys such as, CuCr, CuZn and CuNiSi. The backing plate 333 has a back surface 334, which may optionally have one or more grooves therein, and a support surface 350 to support the sputtering plate 330. A peripheral ledge 352 extends beyond the radius of the sputtering plate 330. The peripheral ledge 352 comprises an outer footing 354 that rests on an isolator 360 in the chamber 100. The isolator 360, typically made from a dielectric or insulator material, electrically isolates and separates the backing plate 333 from the chamber 100, and is typically a ring made from a ceramic material, such as aluminum oxide. The peripheral ledge 352 contains an O-ring groove 362 into which an O-ring 364 is placed to form a vacuum seal. The peripheral ledge 352 of the target 140 is coated may have a protective coating, for example, a twin-wire arc-sprayed aluminum coating, such as CleanCoat™. The sputtering plate 330 can be mounted on the backing plate 333 by, for example, diffusion bonding, by placing the two plates 330,333 on each other and heating the plates 330, 333 to a suitable temperature, typically at least about 200° C. Optionally, the sputtering target 140 may be a unitary structure comprising a sputtering plate and backing plate composed of the same material and having a total depth of from about 0.5 to about 1.3 inches.

During a sputtering process, the target 140, support 130, and upper shield 201a are electrically biased relative to one another by a power supply (not shown). The target 140, upper shield 201a, support 130 and other chamber components connected to the target power supply, operate as a gas energizer 370 energizes the sputtering gas to form a plasma of the sputtering gas. The gas energizer 370 can also include a source coil that is powered by the application of a current through the coil. The plasma formed energetically impinges upon and bombards the sputtering surface 139 of the target 140 to sputter material off the surface 139 onto the substrate 104.

The sputtering gas is introduced into the chamber 100 through a gas delivery system 372, which provides gas from a gas supply 374 via conduits having gas flow control valves, such as a mass flow controllers, to pass a set flow rate of the gas therethrough. The gases are fed to a mixing manifold (not shown) in which the gases are mixed to from a desired process gas composition and fed to a gas distributor 377 having gas outlets in the chamber 100, to distribute gas thereto. The process gas may comprise a non-reactive gas, such as argon or xenon, which is capable of energetically impinging upon and sputtering material from the target 140. The process gas may also comprise a reactive gas, such as one or more of an oxygen-containing gas and a nitrogen-containing gas, that are capable of reacting with the sputtered material to form a layer on the substrate 104. Spent process gas and byproducts are exhausted from the chamber 100 through an exhaust 380 which includes an exhaust port 382 that receive spent process gas and pass the spent gas to an exhaust conduit having a throttle valve to control the pressure of the gas in the chamber 100. The exhaust conduit is connected to one or more exhaust pumps. Typically, the pressure of the sputtering gas in the chamber 100 is set to sub-atmospheric levels, such as a vacuum environment, for example, gas pressures of 1 mTorr to 400 mTorr.

The chamber 100 is controlled by a controller 400 that comprises program code having instruction sets to operate components of the chamber 100 to process substrates 104 in the chamber 100. For example, the controller 400 can comprise program code that includes substrate positioning instruction sets to operate the substrate support 130 and a substrate transfer mechanism; gas flow control instruction sets to operate gas flow control valves to set a flow of sputtering gas to the chamber 100; gas pressure control instruction sets to operate the exhaust throttle valve to maintain a pressure in the chamber 100; gas energizer control instruction sets to operate the gas energizer 370 to set a gas energizing power level; temperature control instruction sets to control a temperature control system in the support 130 or wall 116 to set temperatures of various components in the chamber 100; and process monitoring instruction sets to monitor the process in the chamber 100.

The components of the process kit 200, such as the upper and lower shields 201a,b significantly increase the number of process cycles and processing time that the process kit 200 can be used in the chamber 100 without removing the process kit 200 for cleaning. This is accomplished by increasing the adhesion of sputtered deposits to the surfaces of the process kit 200 components by temperature control and surface finish. The components of the process kit 200 are designed to increase, as well as control thermal conductivity because the expansion and contraction of these parts, due to rapid heating and cooling, results in the flaking or shedding of particles of sputtered deposits, which results in substrate contamination.

The present invention has been described with reference to certain preferred versions thereof, however, other versions are possible. For example, the upper and lower shields 201a,b of the process kit 200 can be used in other types of applications and chambers, as would be apparent to one of ordinary skill. Therefore, the spirit and scope of the appended claims should not be limited to the description of the preferred versions contained herein.

1. An upper shield for encircling a sputtering target in a substrate processing chamber, the sputtering target having an inclined perimeter edge, the upper shield comprising:
(a) a top ring comprising a radially inward bulge, the bulge having an arcuate surface shaped to surround the inclined perimeter edge of the sputtering target;
(b) a support ledge below the top ring, the support ledge extending radially outward; and
(c) a cylindrical band extending downwardly from the support ledge, the cylindrical band comprising:
(1) a radially inward surface having a sloped plane and a substantially vertical plane;
(2) a radially outward surface having a plurality of steps.

2. A shield according to claim 1 wherein the sloped plane of the radially inward surface of the cylindrical band comprises an angle of from about 7 to about 14 degrees relative to the substantially vertical plane.

3. A shield according to claim 1 wherein the radially outward surface of the cylindrical band comprises first, second and third steps.

4. A shield according to claim 3 wherein the steps are joined by inclined planes.

5. A shield according to claim 3 wherein the third step extends downwardly from the inclined plane and terminates in a rounded edge.

6. A shield according to claim 3 wherein the thickness of the third step is less than the thickness of the first and second steps.

7. A shield according to claim 6 wherein the thickness of the third step is from about 0.05 to about 0.3 inches.

8. A shield according to claim 1 wherein the support ledge comprises a bottom surface having a plurality of semicircular protrusions to align the shield with an adapter.

9. A shield according to claim 8 wherein the support ledge comprises a top surface having a plurality of semicircular cutouts.

10. A shield according to claim 1 wherein the top ring, support ledge and cylindrical band form a unitary structure.

11. A shield according to claim 10 wherein the unitary structure is composed of aluminum.

12. A shield according to claim 11 wherein a surface of the shield comprises a twin-wire aluminum arc-spray coating.

13. A shield according to claim 12 wherein the aluminum coating has an average surface roughness of from about 600 to about 2600 microinches.

14. A process kit for placement about a sputtering target and a substrate support in a substrate processing chamber, the process kit comprising:
(a) the shield of claim 1 to encircle the sputtering target;
(b) a lower shield for placement around the shield of claim 1; and
(c) a ring assembly comprising:
(1) a cover ring for placement about the substrate support; and
(2) a deposition ring supporting the cover ring.

15. A lower shield for placement about an upper shield and a substrate support in a substrate processing chamber, the substrate support having a peripheral edge, the lower shield comprising:
an annular band extending downwardly into a curved joint; and
an inwardly projecting lip extending horizontally from the curved joint, the inwardly projecting lip comprising a radially inward edge that at least partially surrounds the peripheral edge of the substrate support.

16. A shield support assembly for placement about a sputtering target, the shield support assembly comprising:
(a) an upper shield comprising:
(1) a top ring comprising an inner surface that surrounds a sputtering surface of the sputtering target;
(2) a support ledge below the top ring, the support ledge extending radially outward and comprising a plurality of protrusions, each protrusion comprising a semicircular shape; and
(3) a cylindrical band extending downwardly from the support ledge;
(b) an adapter to support the shield, the adapter having at least one cutout shaped and sized to receive at least one of the plurality of protrusions to align the shield to the adapter; and
(c) a plurality of screws to secure the upper shield to the adapter, thereby increasing conductance between the upper shield and the adapter.

17. An assembly according to claim 16 wherein the plurality of screws is 12 screws.

18. An assembly according to claim 16 wherein the top ring, support ledge and cylindrical band form a unitary structure.

19. An assembly according to claim 18 wherein the unitary structure is composed of aluminum.

20. A substrate processing chamber comprising:
(a) a substrate support comprising a receiving surface for a substrate;
(b) the shield support assembly of claim 16 for placement about the substrate support;
(c) a lower shield for placement about the upper shield;
(d) a gas distributor to distribute a process gas in the chamber;
(e) a gas energizer to energize the process gas; and
(f) a gas exhaust to exhaust the process gas.

21. A lower shield for placement between an upper shield and sidewall of a substrate processing chamber, and to surround a substrate support having a peripheral edge, the lower shield comprising:
(a) an annular band having an end;
(b) an inwardly projecting lip extending radially inwardly from the end of the annular band; and
(c) a radially inward edge extending from the inwardly projecting lip to at least partially surround the peripheral edge of the substrate support.

22. A shield according to claim 21 wherein the inwardly projecting lip extends horizontally from the end of the annular band.

23. A shield according to claim 21 comprising a curved joint between the end of the annular band and the inwardly projecting lip.

24. A shield according to claim 21 wherein the upper shield comprises an outer surface and wherein at least a portion of the annular band encircles at least a part of the outer surface of the upper shield.

25. A shield according to claim 21 wherein the inwardly projecting lip is sloped downwards from the end of the annular band.

26. A shield according to claim 25 comprising a rounded corner where the inwardly projecting lip meets the radially inward edge.

27. A shield according to claim 21 composed of aluminum.

28. A shield according to claim 21 wherein a surface of the shield comprises a twin-wire aluminum arc-spray coating.

29. A shield according to claim 28 wherein the twin-wire aluminum arc-spray coating comprises an average surface roughness of from about 600 to about 2600 microinches.

30. A process kit for placement about a sputtering target and a substrate support in a substrate processing chamber, the process kit comprising:
(a) a lower shield according to claim 21 to encircle the sputtering target;
(b) an upper shield for placement around the lower shield; and
(c) a ring assembly comprising:
(1) a cover ring for placement about the substrate support; and
(2) a deposition ring supporting the cover ring.

31. A lower shield for placement about an upper shield and a substrate support in a substrate processing chamber, the substrate support having a peripheral edge, the lower shield comprising:
(a) an annular band extending downwardly; and
(b) an inwardly projecting lip extending horizontally from the annular band, the inwardly projecting lip comprising a radially inward edge that at least partially surrounds the peripheral edge of the substrate support.

32. A shield according to claim 31 comprising a curved joint between the annular band and the inwardly projecting lip.

33. A cover ring for placement about a substrate support and a deposition ring in a substrate processing chamber, the cover ring comprising:
(a) a wedge comprising (i) a top surface that extends around the substrate support, and (ii) a projecting brim overlying the deposition ring;
(b) outer and inner legs extending downwardly from the wedge; and
(c) a footing which rests on the deposition ring to support the cover ring.

34. A cover ring according to claim 33 wherein the inner leg has a smaller height than the outer leg.

35. A cover ring according to claim 33 wherein the deposition ring comprises a side, and wherein the inner leg comprises a sloped inner surface that meets the side of the deposition ring.

36. A cover ring according to claim 33 wherein the inner leg is located radially outward of the footing.

37. A cover ring according to claim 33 wherein the outer leg terminates in a rounded bottom.

38. A cover ring according to claim 33 wherein the projecting brim comprises an undersurface that is spaced apart from and at least partially covers the deposition ring.

39. A cover ring according to claim 33 fabricated from a material that resists erosion by a sputtering plasma.

40. A cover ring according to claim 33 comprising stainless steel titanium or aluminum.

41. A cover ring according to claim 33 comprising a ceramic material.

42. A cover ring according to claim 33 comprising a twin-wire arc-sprayed aluminum coating.
